(19) United States
(12) Patent Application Publication
(10) Pub. No.: US 2010/0085997 A1
(43) Pub. Date: Apr. 8, 2010

(54) NITRIDE-BASED SEMICONDUCTOR LASER DEVICE AND METHOD OF MANUFACTURING THE SAME

(75) Inventors: Gaku Nishikawa, Tottori-shi (JP); Kiyoshi Oota, Neyagawa-shi (JP); Yoshinari Ichihashi, Hashima-shi (JP)

Correspondence Address: DITTHAVONG MORI & STEINER, P.C., 918 Prince Street, Alexandria, VA, 22314, US

(73) Assignee: Sanyo Electric Co., Ltd., Moriguchi-shi (JP)

(21) Appl. No.: 12/575,123

(22) Filed: Oct. 7, 2009

(30) Foreign Application Priority Data
Oct. 7, 2008 (JP) 2008-260205
Oct. 1, 2009 (JP) 2009-229170

(51) Int. Cl. H01S 5/00; H01L 33/00

(52) U.S. Cl. 372/46.01; 438/39; 257/E33.005

(57) ABSTRACT

A nitride-based semiconductor laser device includes a nitride-based semiconductor layer formed on an active layer made of a nitride-based semiconductor, and an electrode layer including a first metal layer, made of Pt, formed on a far side of a surface of the nitride-based semiconductor layer from the active layer, a second metal layer, made of Pd, formed on a surface of the first metal layer, and a third metal layer, made of Pt, formed on a surface of the second metal layer, and having a shape necessary for the device in plan view. A thickness of the third metal layer is at least 10 times and not more than 30 times a thickness of the first metal layer.

### CROSS-REFERENCE TO RELATED APPLICATIONS

The priority application number JP2008-260205, Nitride-Based Semiconductor Laser Device and Method of Manufacturing the Same, Oct. 7, 2008, Gaku Nishikawa et al, JP2009-229170, Nitride-Based Semiconductor Laser Device and Method of Manufacturing the Same, Oct. 1, 2009, Gaku Nishikawa et al, upon which this patent application is based is hereby incorporated by reference.

### BACKGROUND OF THE INVENTION

1. Field of the Invention

The present invention relates to a nitride-based semiconductor laser device and a method of manufacturing the same, and more particularly, it relates to a nitride-based semiconductor laser device comprising a nitride-based semiconductor layer and an electrode layer and a method of manufacturing the same.

2. Description of the Background Art

Recently, a nitride-based semiconductor laser device has been developed as a light source of a pickup for an optical disc corresponding to a next generation DVD or light sources of various displays. Particularly, reduction of a contact resistance of an electrode formed on the semiconductor device is required in order to reduce an operation voltage of the nitride-based semiconductor laser device. At this time, in the nitride-based semiconductor, the carrier concentration of a p-type semiconductor is low, and hence it is difficult to form a p-side electrode obtaining an excellent ohmic property.

Therefore, a nitride-based semiconductor laser device formed with a p-side electrode layer having an excellent ohmic property by employing a Pd-based material as electrode materials and a method of manufacturing the same is proposed in general, as described in Japanese Patent Laying-Open No. 2002-305358, for example.

The aforementioned Japanese Patent Laying-Open No. 2002-305358 discloses a nitride-based semiconductor laser device comprising a p-side electrode layer formed by stacking a Pt electrode layer and a Pd-based electrode layer in this order on a p-side semiconductor layer made of a nitride-based semiconductor and a method of forming the same. In this nitride-based semiconductor laser device, while adhesive force between the p-side electrode layer and the p-side semiconductor layer is improved by a Pt layer in contact with the p-side semiconductor layer, the p-side electrode layer can obtain a low contact resistance by the Pd-based electrode layer. In a manufacturing process for the nitride-based semiconductor laser device, the Pt electrode layer and the Pd-based electrode layer are stacked in this order on the p-side semiconductor layer to have a prescribed width and the Pd-based electrode layer is thereafter employed as a mask for etching a prescribed region from the Pd-based electrode layer side toward the p-side semiconductor layer, thereby forming a ridge stripe having a prescribed width on the p-side semiconductor layer. Thereafter, an SiO₂ film is formed on the p-side semiconductor layer (including a portion of the p-side electrode layer) by plasma CVD, and an upper surface of the Pd-based electrode layer is exposed by selectively removing the SiO₂ film on a region corresponding to the p-side electrode layer. Finally, a pad electrode is formed on the exposed Pd-based electrode layer.

In the nitride-based semiconductor laser device and the method of forming manufacturing the same disclosed in the aforementioned Japanese Patent Laying-Open No. 2002-305358, however, the surface, in contact with the pad electrode, of the Pd-based electrode layer conceivably tends to alter. More specifically, in the manufacturing process after forming the ridge stripe, when the upper surface of the Pd-based electrode layer is exposed by selectively removing the SiO₂ film on the p-side electrode layer by dry etching for example, an alteration layer of C or an alteration layer such as a Pd oxide film may be formed on the surface of the Pd-based electrode layer due to collision of carbon atoms (C) or oxygen atoms (O) with the surface of the Pd-based electrode layer in etching with fluorocarbon-based (C—F based) gas and in asking with O₂ gas. Thus, in the nitride-based semiconductor laser device and the method of forming the same described in the aforementioned Japanese Patent Laying-Open No. 2002-305358, the alteration layer is disadvantageously formed on the surface of the p-side electrode layer. Particularly, the alteration layer formed in the manufacturing process deteriorates the ohmic property (contact resistance) of the p-side electrode layer, and hence the operation voltage of the semiconductor laser device is disadvantageously increased.

### SUMMARY OF THE INVENTION

A nitride-based semiconductor laser device according to a first aspect of the present invention comprises a nitride-based semiconductor layer formed on an active layer made of a nitride-based semiconductor, and an electrode layer including a first metal layer, made of Pt, formed on a far side of a surface of the nitride-based semiconductor layer from the active layer, a second metal layer, made of Pd, formed on a surface of the first metal layer, and a third metal layer, made of Pt, formed on a surface of the second metal layer, and having a prescribed shape in plan view, wherein a thickness of the third metal layer is at least 10 times and not more than 30 times a thickness of the first metal layer.

As hereinabove described, the nitride-based semiconductor laser device according to the first aspect of the present invention comprises the electrode layer including the third metal layer made of Pt formed on the surface of the second metal layer made of Pd, whereby an outermost surface of the electrode layer is formed by the third metal layer of Pt, and hence the surface, in contact with a pad electrode or the like, of the third metal layer of Pt is difficult to be altered in the manufacturing process as compared with a semiconductor laser device comprising an electrode layer having an outermost surface of a Pd layer, for example. Particularly, also when an upper surface of the third metal layer made of Pt is exposed by dry etching with C—F based gas and by asking with O₂ gas, for example, after forming the electrode layer so as to have the outermost surface of the third metal layer made of Pt has a property of being difficult to chemically react with etching gas as compared with Pd or the like made of and hence the alteration layer (by-product such as a Pt oxide film) can be inhibited from generation on the surface of the third metal layer made of Pt layer. Consequently, the alteration layer can be inhibited from formation on the surface of the electrode layer due to the manufacturing process of the semiconductor laser device.

The third metal layer made of Pt is formed on the surface of the second metal layer made of Pd, whereby the third metal layer made of Pt constituting the outermost layer inhibits electrode materials scattering in etching from adhering to side surfaces of the electrode layer formed by etching when dry etching or the like through the electrode layer serving as a mask, to form a ridge stripe on the nitride-based semiconductor layer. Thus, the width of the p-side electrode layer made of Pt or Pd can be inhibited from increase with progression of etching, as compared with a case where the quantity of adherence of the electrode materials is remarkably large, e.g., a case where the third metal layer made of Pt is not formed on the outermost surface. Thus, the ridge stripe having substantially the same width as that of the mask can be formed on the nitride-based semiconductor layer.

In the aforementioned nitride-based semiconductor laser device according to the first aspect, the first metal layer is preferably formed to partially cover the surface of the nitride-based semiconductor layer, and the second metal layer is preferably formed to cover the surface of the first metal layer and the surface, not covered by the first metal layer, of the nitride-based semiconductor layer. According to this structure, the second metal layer is formed with a portion covering the surface of the first metal layer and a portion covering the surface of the nitride-based semiconductor layer, and therefore a surface area of the second metal layer on the n-type nitride-based semiconductor layer side can be increased and hence adhesiveness of the electrode layer with respect to the surface of the nitride-based semiconductor layer can be improved.

In this case, the first metal layer is preferably formed in a state where Pt is distributed in the form of islands or a state where Pt is in the form of a net. According to this structure, the second metal layer made of Pd covers the surface of the first metal layer made of Pt provided in the form of islands or a net, and penetrates into a clearance between the first metal layer formed in the form of islands or a net and the nitride-based semiconductor layer exposed from the first metal layer to cover the surface of the nitride-based semiconductor layer, and hence the surface area of the second metal layer can be easily increased.

In the aforementioned nitride-based semiconductor laser device according to the first aspect, the first metal layer preferably has the thickness in the range of at least about 1 nm and not more than about 2 nm. According to this structure, the first metal layer made of Pt can be easily and reliably formed on the surface of the nitride-based semiconductor layer in the state of being in the form of islands or a net.

In the aforementioned nitride-based semiconductor laser device according to the first aspect, the thickness of the first metal layer is preferably smaller than a thickness of the second metal layer. According to this structure, the electrode layer having an excellent ohmic property by the second metal layer employing Pd can be formed while maintaining adhesive force between the first metal layer and the nitride-based semiconductor layer by the electrode layer employing Pt.

In the aforementioned nitride-based semiconductor laser device according to the first aspect, the second metal layer preferably has the thickness in the range of at least about 5 nm and not more than about 20 nm. According to this structure, the electrode layer allowing maintenance of adhesive force between the first metal layer and the nitride-based semiconductor layer and an excellent ohmic property by the second metal layer can be easily formed by setting the thickness of the second electrode layer within the aforementioned ranges.

In the aforementioned nitride-based semiconductor laser device according to the first aspect, a thickness of the second metal layer is preferably smaller than the thickness of the third metal layer. According to this structure, the electrode materials scattering by etching or the like can be suppressed when forming the ridge stripe on the nitride-based semiconductor layer by dry etching through the electrode layer serving as a mask. Thus, a ridge stripe having a desired ridge width can be easily formed.

In this case, the third metal layer preferably has the thickness in the range of at least about 10 nm and not more than about 30 nm. According to this structure, the quantity of scatter of the electrode materials in etching can be suppressed within a proper range by setting the thickness of the third metal layer within the aforementioned range, and hence a ridge stripe having a desired ridge width can be easily formed on the nitride-based semiconductor layer.

In the aforementioned nitride-based semiconductor laser device according to the first aspect, the prescribed shape is preferably substantially the same shape as a shape of a current path of the active layer formed below the electrode layer in plan view. According to this structure, a current flowing at a width of the electrode layer (first metal layer) can be supplied to the active layer over a substantially overall region having a planar shape of the current path. The current path is formed to have substantially the same width as that of the first metal layer, and hence dispersion of a resistant value of the current path along the cavity direction of the laser device can be suppressed.

In the aforementioned nitride-based semiconductor laser device according to the first aspect, the prescribed shape is preferably substantially the same shape as a shape of an optical waveguide formed below the electrode layer in plan view. According to this structure, the size (sectional shape) of the optical waveguide formed around the active layer substantially uniforms along an extensional direction of the electrode layer, and hence a stable laser beam can be emitted.

The aforementioned nitride-based semiconductor laser device according to the first aspect preferably further comprises a ridge formed on the far side and formed below the electrode layer to have substantially the same shape as the prescribed shape of the electrode layer in plan view, wherein the first metal layer made of Pt is preferably formed on the ridge. According to this structure, the adhesive force of the electrode layer with respect to the nitride-based semiconductor layer is improved by the first metal layer made of Pt, and hence the nitride-based semiconductor layer is difficult to be separated from the electrode layer. Thus, a current can be reliably supplied to the active layer from the electrode layer through the ridge.

In this case, a width of a near side of the first metal layer to the nitride-based semiconductor layer is preferably larger than that of a far side of the third metal layer from the nitride-based semiconductor layer. According to this structure, the width of the first metal layer, in contact with the nitride-based semiconductor layer, located on the lower portion is larger than the width of the second or third metal layer stacked on the upper layer side, and hence the electrode layer reliably adhering to the surface of the nitride-based semiconductor layer can be formed through the first metal layer.

In the aforementioned structure in which the first metal layer is formed on the ridge, the electrode layer preferably includes a side surface extending along an extensional direction of the ridge, and the side surface is preferably inclined to increase a width of the electrode layer from the third metal layer toward the first metal layer. According to this structure, the width of the first metal layer, in contact with the nitride-based semiconductor layer, located on the lower portion is larger than the width of the second or third metal layer stacked on the upper layer side, and hence a current can be easily supplied to the ridge formed by the nitride-based semiconductor layer through the first metal layer.

In the aforementioned nitride-based semiconductor laser device according to the first aspect, the electrode layer is preferably an ohmic electrode. According to this structure, the electrode layer in which an alteration layer is inhibited from formation on the surface can be effectively employed as the ohmic electrode, and hence a current for operating the laser device can be reliably supplied to the active layer through the ohmic electrode.

In this case, the nitride-based semiconductor laser device according to the first aspect preferably further comprises a pad electrode, containing Au, formed on a side of the third metal layer opposite to the second metal layer, wherein the pad electrode is preferably in contact with a surface of the third metal layer. According to this structure, an ohmic resistance value between the third metal layer made of Pt and the pad electrode made of Pt which is difficult to alter through the manufacturing process are reduced, and hence an electrical property of the laser device can be stabilized.

In the aforementioned structure where the nitride-based semiconductor laser device further comprises the pad electrode, the pad electrode preferably contains Au. According to the structure, the ohmic resistance value between the third metal layer made of Pt and the pad electrode containing Au can be reliably reduced.

In the aforementioned nitride-based semiconductor laser device according to the first aspect, the nitride-based semiconductor layer preferably includes a p-type semiconductor layer, and the electrode layer is preferably a p-side electrode. According to this structure, the electrode layer having a reduced ohmic resistance value is employed as a p-side electrode for injecting a current to the laser device, and hence a lower voltage and higher output of the laser device can be achieved.

A method of manufacturing a nitride-based semiconductor laser device according to a second aspect of the present invention comprises steps of forming a nitride-based semiconductor layer on an active layer made of a nitride-based semiconductor, stacking a first metal layer made of Pt, a second metal layer made of Pd, a third metal layer, made of Pt, having a thickness of at least 10 times and not more than 30 times a thickness of the first metal layer and a first mask layer in this order on a far side of a surface of the nitride-based semiconductor layer from the active layer, to form the first, second and third metal layers and the first mask layer in a state of having a prescribed shape in plan view, and forming a ridge having the prescribed shape on the nitride-based semiconductor layer by etching the nitride-based semiconductor layer through the first mask layer and the third, second and first metal layers serving as masks.

As hereinabove described, the method of manufacturing a nitride-based semiconductor laser device according to the second aspect of the present invention comprises the step of stacking the first metal layer made of Pt, the second metal layer made of Pd, the third metal layer made of Pt and the first mask layer in this order on the surface of the nitride-based semiconductor layer, to form the first, second and third metal layers and the first mask layer in the state of having the prescribed shape in plan view and the step of forming the ridge having the prescribed shape by etching the nitride-based semiconductor layer through the first mask layer and the third, second and first metal layers serving as the masks, whereby the electrode layer in which the third metal layer of Pt constitutes an outermost surface is formed, and hence the surface, in contact with a pad electrode or the like, of the third metal layer of Pt is difficult to be altered in the manufacturing process as compared with a semiconductor laser device comprising an electrode layer having an outermost surface of a Pd layer. Particularly, also when an upper surface of the third metal layer made of Pt is exposed by dry etching with C—F based gas and by asking with O₂ gas, for example, after forming the electrode layer so as to have the outermost surface of the third metal layer made of Pt, Pt has a property of being difficult to chemically react with etching gas as compared with Pd, and hence the alteration layer (by-product such as a Pt oxide film) can be inhibited from generation on the surface of the third metal layer made of Pt. Consequently, the alteration layer can be inhibited from formation on the surface of the electrode layer due to the manufacturing process of the semiconductor laser device.

In the aforementioned method of manufacturing a nitride-based semiconductor laser device according to the second aspect, the step of stacking the first, second and third metal layers and the first mask layer in this order, to form the first, second and third metal layers and the first mask layer in the state of having the prescribed shape in plan view preferably includes a step of forming the first, second and third metal layers in a state of having the prescribed shape in plan view by etching the third, second and first metal layers through the first mask layer serving as a mask. According to this structure, the width of the first metal layer, in contact with the nitride-based semiconductor layer, located on the lower portion is larger than the width of the second or third metal layer stacked on the upper layer side, and hence the electrode layer reliably adhering to the surface of the nitride-based semiconductor layer can be formed.

The aforementioned method of manufacturing a nitride-based semiconductor laser device according to the second aspect preferably further comprises steps of forming a current blocking layer made of an insulating film on a surface of the nitride-based semiconductor layer and surfaces of the third, second and first metal layers formed in the state of having the prescribed shape, forming a second mask layer having an opening to correspond to a portion located above at least the ridge of the current blocking layer, exposing a surface of the third metal layer by removing the current blocking layer on a portion exposed from the opening through the second mask serving as a mask, and removing the second mask layer. According to this structure, Pt is employed for the third metal layer constituting the outermost surface when forming the current blocking layer by plasma CVD, when removing the current blocking layer on the portion exposed from the opening by dry etching, or when removing the second mask layer, and hence alteration layer can be easily inhibited from formation on the surface of the electrode layer.

In the aforementioned method of manufacturing a nitride-based semiconductor laser device according to the second aspect, the step of exposing the surface of the third metal layer preferably includes a step of exposing the surface of the third metal layer made of Pt by dry etching the current blocking layer on the portion exposed from the opening of the second mask layer. According to this structure, the quantity of electrode materials scattering in etching is small and formation of the alteration layer is reduced in the third metal layer made of Pt, and hence the ohmic resistance value between the third metal layer and the pad electrode can be reduced also when the pad electrode or the like is formed on the surface of the third metal layer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view showing a structure of a nitride-based semiconductor laser device according to an embodiment of the present invention;

FIG. 2 is an enlarged sectional view showing a detailed structure of the nitride-based semiconductor laser device according to the embodiment of the present invention;

FIGS. 3 to 10 are diagrams for illustrating a manufacturing process for the nitride-based semiconductor laser device according to the embodiment of the present invention;

FIG. 11 is a photomicrograph obtained by observing a sectional device structure in the vicinity of a ridge of the semiconductor laser device formed through the manufacturing process of the nitride-based semiconductor laser device according to the embodiment of the present invention with a scanning electron microscope;

FIG. 12 is a photomicrograph obtained by observing a sectional device structure in the vicinity of a ridge of a semiconductor laser device formed through a manufacturing process of a conventional semiconductor laser device with the scanning electron microscope;

FIG. 13 is a diagram showing a result of confirmatory experiment 2 conducted for investigating an optimum value of a thickness of a first metal layer (Pt layer) of the present invention;

FIGS. 14 and 15 are diagrams showing a result of confirmatory experiment 3 conducted for investigating an optimum value of a thickness of a second metal layer (Pd layer) of the present invention;

FIG. 16 is a diagram schematically showing a state where electrode materials scattering from a p-side electrode layer in dry etching adheres to side surfaces of a p-side electrode layer; and

FIG. 17 is a diagram showing a result of confirmatory experiment 4 conducted for investigating an optimum value of a thickness of a third metal layer (Pt layer) of the present invention.

### DESCRIPTION OF THE PREFERRED EMBODIMENTS

### Embodiments

Embodiments of the present invention will be hereinafter described with reference to the drawings.

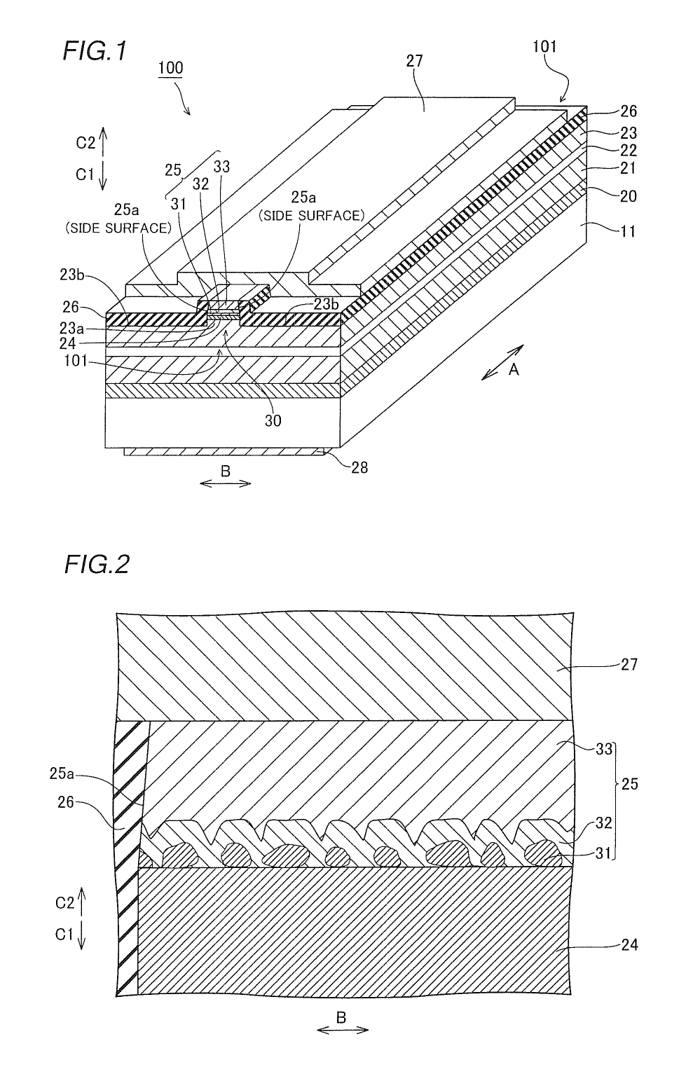

A structure of a nitride-based semiconductor laser device 100 according to an embodiment of the present invention will be now described with reference to FIGS. 1 and 2.

In the nitride-based semiconductor laser device 100 according to this embodiment, a buffer layer 20 made of AlGaN is formed on an n-type GaN substrate 11, as shown in FIG. 1. An n-type cladding layer 21 made of n-type AlGaN, an MQW active layer 22 formed by alternately stacking barrier layers (not shown) made of InGaN and well layers (not shown) made of InGaN, and a p-type cladding layer 23 made of AlInGaN and having a projecting portion 23a and planar portions 23b are formed on the buffer layer 20. A p-type contact layer 24 made of InGaN is formed on the projecting portion 23a of the p-type cladding layer 23. The projecting portion 23a of the p-type cladding layer 23 and the p-type contact layer 24 form a ridge 30. The ridge 30 is formed to have a width of about 1.5 μm in a device width direction (direction B) perpendicular to a cavity direction and extend along the cavity direction (direction A) in a striped manner. This ridge 30 forms an optical waveguide around the MQW active layer 22 located on a lower portion of the ridge 30. Each of GaN, AlGaN, InGaN and AlInGaN is an example of the “nitride-based semiconductor” in the present invention. The MQW active layer 22 is an example of the “active layer” in the present invention, and each of the p-type cladding layer 23 and the p-type contact layer 24 is an example of the “nitride-based semiconductor layer” in the present invention.

A p-side ohmic electrode 25 is formed on the p-type contact layer 24. The p-side ohmic electrode 25 is an example of the “electrode layer” in the present invention.

According to this embodiment, the p-side ohmic electrode 25 is formed by stacking a Pt electrode layer 31 having a thickness of about 1 nm, a Pd electrode layer 32 having a thickness of about 5 nm, and a Pt electrode layer 33 having a thickness of about 10 nm successively from a side closer to the p-type contact layer 24, as shown in FIG. 1. Therefore, a thickness of the Pt electrode layer 33 is substantially 10 times a thickness of the Pt electrode layer 31. The p-side ohmic electrode 25 is formed above the projecting portion 23a to have substantially the same width as that of the ridge 30 in the direction B. The Pt electrode layer 31, the Pd electrode layer 32 and the Pt electrode layer 33 are examples of the “first metal layer”, the “second metal layer” and the “third metal layer” in the present invention, respectively.

When the Pt electrode layer 31 has a thickness of about 1 nm, the Pt electrode layer 31 is formed in a state where Pt is distributed in the form of islands on a surface of the p-type contact layer 24, as in a section of the p-side ohmic electrode 25 microscopically shown in FIG. 2. Pt is distributed in the form of islands, so that the Pt electrode layer 31 is not a completely continuous film. A portion formed by connecting parts of the adjacent islands of Pt also exists, and hence the Pt electrode layer 31 is formed to partially spread in the form of a net on the p-type contact layer 24 in plan view. The thickness of the Pt electrode layer 31 is preferably in the range of at least about 1 nm and not more than about 2 nm.

As shown in FIG. 2, the Pd electrode layer 32 covering the Pt electrode layer 31 is formed on an interface between the p-type contact layer 24 and the p-side ohmic electrode 25 to be partially in contact with the surface, not in contact with the Pt electrode layer 31, of the p-type contact layer 24 in addition to the Pt electrode layer 31 distributed in the form of islands. Therefore, the p-side ohmic electrode layer 25 is so formed that both of the Pt electrode layer 31 distributed in the form of islands and the partial Pd electrode layer 32 are in contact with the surface of the p-type contact layer 24. The Pd electrode layer 32 is formed to preferably have a thickness in the range of at least about 5 nm and not more than about 20 nm, and the thickness of the Pd electrode layer 32 is preferably larger than that of the Pt electrode layer 31.

The Pt electrode layer 33 is formed to preferably have a thickness in the range of at least about 10 nm and not more than about 30 nm. According to this embodiment, the thickness (about 10 nm) of the Pt electrode layer 33 is substantially 10 times the thickness (about 1 nm) of the Pt electrode layer 31.

According to this embodiment, the p-side ohmic electrode layer 25 is so formed that a pair of side surfaces 25a (see FIG. 1) extending along the cavity facet are inclined in a direction in which the width of the electrode layer in the direction B increases from the Pt electrode layer 33 toward the Pt electrode layer 31, as shown in FIGS. 1 and 2. In other words, the p-side ohmic electrode layer 25 has a shape in which the width in the direction B is slightly tapered upward (direction C2) from the ridge 30. The ridge 30 (see FIG. 1) is formed to extend along the cavity direction (direction A) in a state of having substantially the same width as the width of the Pt electrode layer 31, which is located on an undermost layer of the p-side ohmic electrode layer 25, in the direction B.

A current blocking layer 26 made of SiO₂ is formed to cover upper surfaces of the planar portions of the p-type cladding layer 23 and side surfaces of the projecting portion 23a of the p-type cladding layer 23 and the p-side contact layer 24, which are side surfaces of the ridge 30, and side surfaces of the p-side ohmic electrode 25. A p-side pad electrode 27 including a Ti layer having a thickness of about 10 nm, a Pd layer having a thickness of about 100 nm and an Au layer having a thickness of about 300 nm is formed to be in contact with an upper surface of the p-side ohmic electrode 25. An n-side electrode 28 including an Si layer having a thickness of about 1 nm, an Al layer having a thickness of about 6 nm, an Si layer having a thickness of about 2 nm, a Pd layer having a thickness of about 6 nm and an Au layer having a thickness of about 300 nm successively from a side closer to the n-type GaN substrate 11 is formed on a lower surface of the n-type GaN substrate 11.

In the nitride-based semiconductor laser device 100, a pair of cavity facets 110 substantially perpendicular to a main surface of the n-type GaN substrate 11 are formed on both ends of the cavity direction, as shown in FIG. 1. Dielectric multilayer films (not shown) made of AlN or Al₂O₃ are formed on the pair of cavity facets 110 by facet coating treatment in a manufacturing process. A multilayer film made of GaN, AlN, BN, Al₂O₃, SiO₂, ZrO₂, Ta₂O₅, Nb₂O₅, La₂O₃, SiN, AlON and MgF₂, or Ti₃O₅ or Nb₂O₃ which is a material different in an alloyed ratio from these can be employed for the dielectric multilayer film.

In the nitride-based semiconductor laser device 100, an optical guide layer, a carrier blocking layer or the like may be formed between the n-type cladding layer 21 and the MQW active layer 22. A contact layer or the like may be formed on a side of the n-type cladding layer 21 opposite to the MQW active layer 22. Alternatively, an optical guide layer, a carrier blocking layer or the like may be formed between the MQW active layer 22 and the p-type cladding layer 23. The MQW active layer 22 may have a single-layer, a single quantum well structure or the like.

A manufacturing process for the nitride-based semiconductor laser device 100 according to the embodiment of the present invention will be now described with reference to FIGS. 1 to 10.

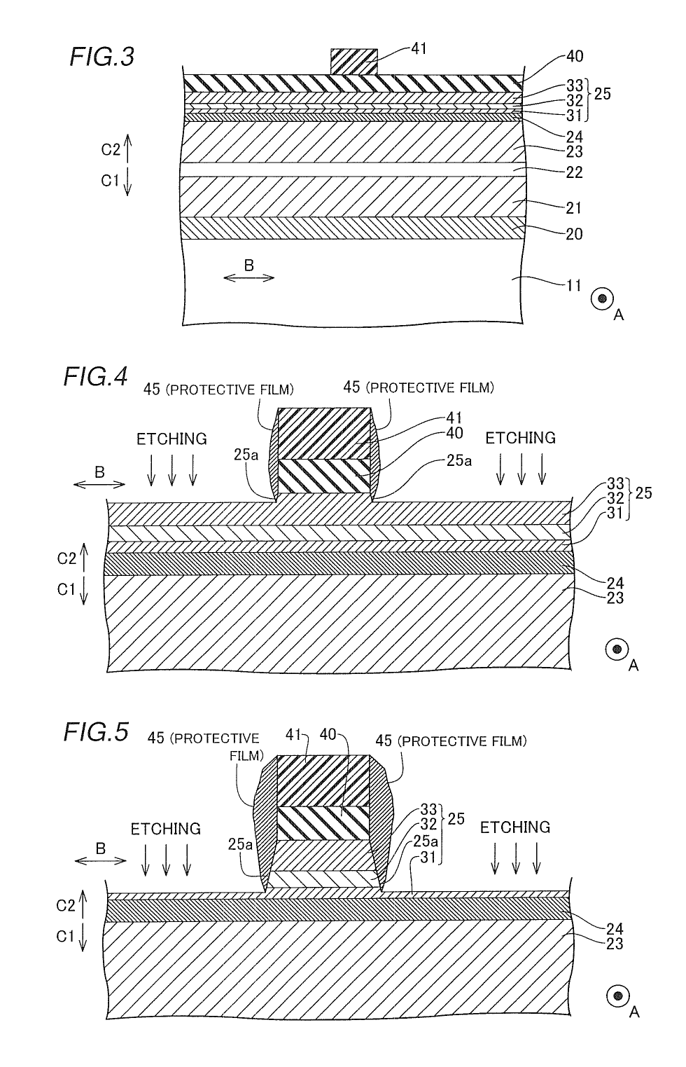

As shown in FIG. 3, the buffer layer 20, the n-type cladding layer 21, the MQW active layer 22, the p-type cladding layer 23, the p-type contact layer 24 are successively stacked on the n-type GaN substrate 11 by MOCVD. Thereafter, the p-side ohmic electrode 25 is formed on the p-type contact layer 24 by vacuum deposition.

At this time, according to this embodiment, the Pt electrode layer 31 having a thickness of about 1 nm, the Pd electrode layer 32 having a thickness of about 5 nm and the Pt electrode layer 33 having a thickness of about 10 nm are stacked successively from the side closer to the p-type contact layer 24, thereby forming the p-side ohmic electrode 25, as shown in FIG. 2. Thus, the p-side ohmic electrode 25 made of Pt having an outermost surface in a direction C2 is formed.

A mask 40 made of SiO₂is formed on the surface of the p-side ohmic electrode 25 by plasma CVD as shown in FIG. 3. Thereafter, resist patterns 41 each extending in the direction A in a striped manner and having a width of about 1.5 μm in the direction B are formed on the mask 40 by photolithography.

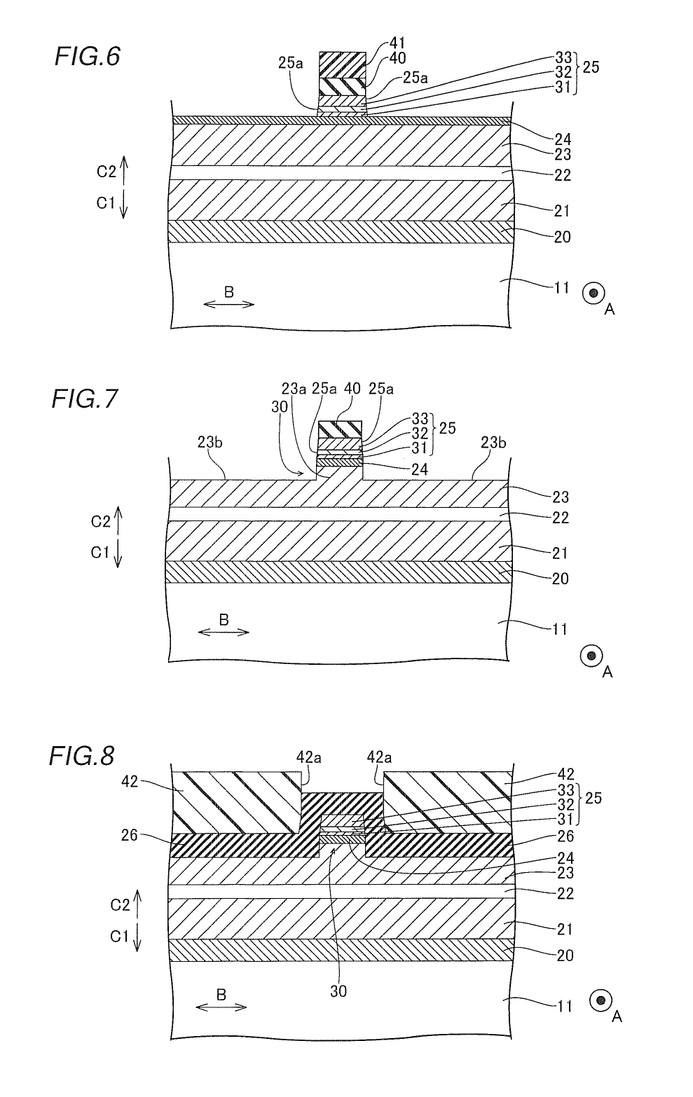

As shown in FIG. 4, each resist pattern 41 is employed as a mask for dry-etching the mask 40, thereby patterning the mask 40 to have substantially the same width in the direction B as that of the resist pattern 41. Then the patterned mask 40 is employed as a mask for etching the Pt electrode layer 33, the Pd electrode layer 32 and the Pt electrode layer 31 of the p-side ohmic electrode 25 in a direction Cl from the upper layer toward the lower layer by anisotropic dry etching with CHF₃ gas. At this time, protective films 45 are formed on side surfaces of the resist pattern 41 and the mask 40 following etching of the Pt electrode layer 33. The protective films 45 are films containing fluorocarbon-based substances mainly composed of CF_{X} generated by Fluorocarbon Gas such as CHF₃ gas or CF₄ gas or adherent substances (substances mainly made of Pt or Pd) of electrode materials scattering from the electrode layer in etching. Therefore, the Pt electrode layer 33 is etched in the direction Cl while forming the protective films 45 also on etched surfaces (a pair of the side surfaces 25a) of the Pt electrode layer 33, and hence the etched surfaces (a pair of the side surfaces 25a) of the Pt electrode layer 33 is formed to be obliquely inclined with respect to a direction C, as shown in FIG. 4. The protective films 45 are continuously formed on the etched surfaces with progression of etching. Thus, the side surfaces 25a are gradually formed also on the Pd electrode layer 32 and the Pt electrode layer 31 by continuing the etched surfaces of the Pt electrode layer 33. Therefore, the p-side ohmic electrode 25 formed by etching is formed in a shape in which the width of the metal layer in the direction B increase from the Pt electrode layer 33 toward the Pt electrode layer 31 (from upward to downward) in plan view, as shown in FIG. 6. Then, dry etching ends when reaching the upper surface (C2 side) of the p-type contact layer 24. For simplification of the drawing, the protective films 45 (see FIG. 5) formed on the side surfaces 25a are not illustrated in FIG. 6. Thereafter, the resist pattern 41 and the protective films 45 are removed by cleaning with an organic solvent. The patterned mask 40 is an example of the “first mask layer” in the present invention.

As shown in FIG. 7, the patterned mask 40 and p-side ohmic electrode 25 are employed as masks for etching the p-type contact layer 24 and the p-type cladding layer 23 by anisotropic dry etching with Cl₂ gas, thereby forming the p-type cladding layer 23 constituted by the planar portions 23b and the projecting portion 23a having a height of about 500 nm. At this time, the p-type contact layer 24 and the p-type cladding layer 23 are etched in the direction C2 to have substantially the same widths in the direction B as that of the Pt electrode layer 31. Thus, the ridge 30 (projecting portion 23a) having substantially the same width (about 1.5 μm) as that of the Pt electrode layer, located on the undermost layer in the p-side ohmic electrode 25, in the direction B is formed.

As shown in FIG. 8, the mask 40 (see FIG. 7) remained on the ridge 30 is removed by wet etching. The current blocking layer 26 is formed by plasma CVD or the like to continuously cover the planar portion of the p-type cladding layer 23, the side surfaces of the ridge 30 and the side surfaces 25a and the upper surface (C2 side) of the p-side ohmic electrode 25. Then, a resist pattern 42 is formed to cover a prescribed region of the current blocking layer 26 by photolithography. The resist pattern 42 is patterned to be formed with a striped opening 42a above a region formed with the p-side ohmic electrode 25 (ridge 30). The resist pattern 42 is an example of the “second mask layer” in the present invention.

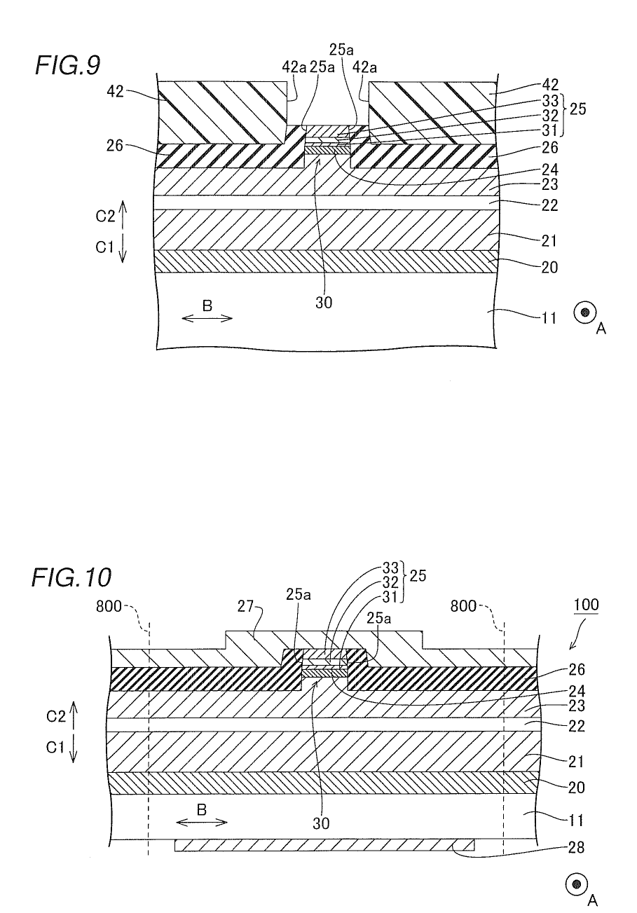

As shown in FIG. 9, the resist pattern 42 is employed as a mask for etching the current blocking layer 26 by anisotropic dry etching with CHF₃ gas or CF₄ gas, thereby removing the current blocking layer 26 on a region corresponding to the opening 42a. Thus, the upper surface of the Pt electrode layer 33 of the p-side ohmic electrode 25 is exposed.

As shown in FIG. 10, the resist pattern 42 (see FIG. 9) is removed by asking with O₂ gas. Thereafter, the p-side pad electrode 27 covering the upper surface of the Pt electrode layer 33 and the upper surface of the current blocking layer 26 and extending in the direction A (see FIG. 1) is formed by photolithography and vacuum deposition. The p-side pad electrode 27 is formed by stacking the Ti layer, the Pd layer and the Au layer successively from a side closer to the ridge 30.

As shown in FIG. 10, after the lower surface of the n-type GaN substrate 11 is so polished that the n-type GaN substrate 11 has a prescribed thickness and an alteration layer caused by polishing is removed by dry etching, the n-side electrode 28 is formed on the lower surface of the n-type GaN substrate 11. The n-side electrode 28 is formed by stacking the Si layer, the Al layer, the Si layer, the Pd layer and the Au layer successively form the side closer to the n-type GaN substrate 11.

Finally, the wafer is cleaved in the form of a bar along the direction B to have a cavity length of about 800 μm, and division (separation) of the wafer into device is performed along the cavity direction (direction A (see FIG. 1)) on positions shown by broken lines 800. Thus, a large number of the nitride-based semiconductor laser devices 100 shown in FIG. 1 are formed.

According to this embodiment, as hereinabove described, the nitride-based semiconductor laser device 100 comprises the p-side ohmic electrode 25 including the Pt electrode layer 33 formed on the surface of the Pd electrode layer 32, whereby the outermost surface of the p-side ohmic electrode 25 is formed by the Pt electrode layer 33, and hence the surface, in contact with the p-side pad electrode 27, of the Pt electrode layer 33 is difficult to be altered in the manufacturing process as compared with a semiconductor laser device comprising an electrode layer having an outermost surface of a Pd layer. Particularly, when the current blocking layer 26 is formed by plasma CVD with silan (SiH₄) gas after forming the p-side ohmic electrode 25 so as to have the outermost surface of the Pt electrode layer 33, Pd is easily silicided while Pt is difficult to be silicided. Further, also when the partial region of the current blocking layer 26 is removed by anisotropic dry etching with CF₄ gas to expose the upper surface of the Pt electrode layer 33, Pt has a property of being difficult to chemically react with etching gas as compared with Pd, and hence the alteration layer can be inhibited from generation on the surface of the Pt electrode layer 33. In the subsequent manufacturing process, also when the resist pattern 42 is removed by asking with O₂ gas, Pt has a low reactive property with O₂ gas, and hence the alteration layer can be inhibited from generation on the surface of the Pt electrode layer 33. Consequently, the alteration layer can be inhibited from formation on the surface of the p-side ohmic electrode 25 due to the manufacturing process of the nitride-based semiconductor laser device 100.

According to this embodiment, the Pt electrode layer 33 is formed on the surface of the Pd electrode layer 32, whereby the thickness of the Pd electrode layer 32 can be reduced by arranging the Pt electrode layer 33 on the outermost surface when the p-side ohmic electrode 25 is employed as the mask for performing anisotropic dry etching and the ridge 30 is formed on the p-type cladding layer 23 and the p-type contact layer 24, and hence the quantity of electrode materials adhering to side walls of the p-side ohmic electrode 25 in etching can be suppressed. Consequently, the width of the p-side ohmic electrode 25 (in the direction B) can be inhibited from remarkable increase with progression of etching as compared with a case where the outermost surface is the electrode layer made of Pd.

According to this embodiment, the Pt electrode layer 31 is formed in the state where Pt is distributed in the form of islands or in the state of being in the form of a net, whereby the Pd electrode layer 32 is in contact with and covers the surface of the Pt electrode layer 31 provided in the form of islands or a net, and penetrates into a clearance between the Pt electrode layer 31 formed in the form of islands or a net and the p-type contact layer 24 exposed from the Pt electrode layer 31 to be in contact with and cover the surface of the p-type contact layer 24, and hence the surface area of the Pd electrode layer 32 can be easily increased. A contact area of the Pd electrode layer 32 with the p-type contact layer 24 is increased and hence adhesiveness of the p-side ohmic electrode 25 with respect to the surface of the p-type contact layer 24 can be reliably improved. Thus, film separation of the p-side ohmic electrode 25 can be suppressed also when the semiconductor device layer is successively subjected to the prescribed manufacturing processes under a higher temperature condition than that in forming the p-side ohmic electrode 25. This also can suppress the deterioration of the ohmic contact characteristic.

According to this embodiment, the thickness of the islandlike or netlike Pt electrode layer 31 is in the range of at least about 1 nm and not more than about 2 nm, whereby the Pt electrode layer 31 can be easily and reliably formed on the surface of the p-type contact layer 24 in the state of being in the form of islands or a net.

According to this embodiment, the thickness (about 1 nm) of the Pt electrode layer 31 is smaller than the thickness (about 5 nm) of the Pd electrode layer 32, whereby the p-side ohmic electrode 25 having an excellent ohmic property by the Pd electrode layer 32 employing Pd can be easily formed while maintaining adhesive force between the p-side ohmic electrode 25 and the p-type contact layer 24 by the Pt electrode layer 31 employing Pt.

According to this embodiment, the Pt electrode layer 31 has the thickness in the range of at least about 1 nm and not more than about 2 nm, and the Pd electrode layer 32 has the thickness in the range of at least about 5 nm and not more than about 20 nm, whereby the p-side ohmic electrode 25 allowing maintenance of adhesive force between the Pd electrode layer 31 and the p-type contact layer 24 and an excellent ohmic property by the Pd electrode layer 32 can be easily formed by setting the thicknesses of the respective electrode layers within the aforementioned ranges.

According to this embodiment, the thickness (about 5 nm) of the Pd electrode layer 32 is smaller than the thickness (about 10 nm) of the Pt electrode layer 33, whereby the electrode materials (quantity of adherence of the electrode materials to the side surfaces of the p-side ohmic electrode 25) scattering by etching can be further suppressed when the p-side ohmic electrode 25 is employed as the mask for performing anisotropic dry etching and the ridge 30 is formed on the p-type cladding layer 23 and the p-type contact layer 24. Thus, the ridge 30 having a desirable ridge width can be formed.

According to this embodiment, the Pd electrode layer 32 has the thickness in the range of at least about 5 nm and not more than about 20 nm, and the Pt electrode layer 33 has the thickness in the range of at least about 10 nm and not more than about 30 nm, whereby the quantity of scatter of the electrode materials (quantity (thickness) of the protective films 45) in etching can be suppressed in a proper range by setting the thicknesses of the respective electrode layers within the aforementioned range, and hence a ridge stripe having a desired ridge width can be easily formed on the nitride-based semiconductor layer.

According to this embodiment, the ridge 30 is formed to have substantially the same width in the direction B as that of the Pt electrode layer 31 of the p-side ohmic electrode 25 in the direction B, and the p-side ohmic electrode 25 is so formed that the Pt electrode layer 31 is in contact with the p-type contact layer 24 of the ridge 30, whereby the adhesive force of the p-side ohmic electrode 25 with respect to the p-type contact layer 24 is improved by the Pt electrode layer 31, and hence the p-side ohmic electrode 25 is difficult to be separated from the p-type contact layer 24. Thus, a current can be reliably supplied to the MQW active layer 22 from the p-side ohmic electrode 25 through the ridge 30. The ridge 30 is formed to have substantially the same width along the cavity direction as that of the Pt electrode layer 31, and hence a current flowing at a width of the p-side ohmic electrode 25 (Pt electrode layer 31) can be supplied to the MQW 22 active layer over a substantially overall region of the nitride-based semiconductor laser device 100 along the cavity direction.

According to this embodiment, the ridge 30 is formed to have substantially the same width along the cavity direction as that of the Pt electrode layer 31, whereby dispersion of a resistant value of the current path along the cavity direction of the nitride-based semiconductor laser device 100 can be suppressed. Further, the size (sectional shape) of the optical waveguide formed around the MQW active layer 22 substantially uniforms along the extensional direction (cavity direction) of the p-side ohmic electrode 25, and hence astable laser beam can be emitted from the nitride-based semiconductor laser device 100.

According to this embodiment, the width of the Pt electrode layer 31 in contact with the p-type contact layer 24 (width in the direction B shown in FIG. 10) is larger than the width of the Pt electrode layer 33 on a side in contact with the p-side pad electrode 27, whereby the p-side ohmic electrode 25 reliably adhering to the surface of the p-type contact layer 24 can be formed through the first metal layer since the width of the Pt electrode layer 31 is larger than the width of the Pd electrode layer 32 or the Pt electrode layer 33 stacked on the upper layer side.

According to this embodiment, the side surfaces of the p-side ohmic electrode 25 formed by etching in the manufacturing process are inclined to increase the width of the electrode layer from the Pt electrode layer 33 toward the Pt electrode layer 31, whereby the width of the Pt electrode layer 31, in contact with the p-type contact layer 24, located on the lower portion is larger than that of the Pd electrode layer 32 or the Pt electrode layer 33 stacked on the upper layer side, and hence a current can be easily supplied to the ridge 30 through the Pt electrode layer 31.

According to this embodiment, the p-side ohmic electrode 25 is formed by the Pt electrode layer 31, the Pd electrode layer 32 and the Pt electrode layer 33, whereby the p-side ohmic electrode 25 in which an alteration layer is inhibited from formation on the surface can be effectively employed, and hence a current for operating the nitride-based semiconductor laser device 100 can be reliably supplied to the MQW active layer 22 through the p-side ohmic electrode 25.

According to this embodiment, the p-side pad electrode 27 containing Au is formed to be in contact with the surface of the Pt electrode layer 33, whereby an ohmic resistance value between the Pt electrode layer 33 and the p-side pad electrode made of Pt which is difficult to alter through the manufacturing process are reduced, and hence an electrical property of the nitride-based semiconductor laser device 100 can be stabilized.

According to this embodiment, the p-side ohmic electrode 25 is formed by the Pt electrode layer 31, the Pd electrode layer 32 and the Pt electrode layer 33, whereby the p-side ohmic electrode 25 having a reduced ohmic resistance value is employed as a p-side electrode for injecting a current to the laser device, and hence a lower voltage and higher output of the nitride-based semiconductor laser device 100 can be achieved.

In the manufacturing process of this embodiment, the current blocking layer 26 on a portion exposed from the opening 42a of the resist pattern 42 is dry etched, so that the surface of the Pt electrode layer 33 is exposed, whereby the quantity of electrode materials (adherent substances mainly composed of Pt) scattering in etching is small in the Pt electrode layer 33, and hence the ohmic resistance value between the Pt electrode layer 33 and the p-side pad electrode 27 can be reduced also when the p-side pad electrode 27 is formed on the surface of the Pt electrode layer 33.

While the p-side ohmic electrode 25 is so formed that the thicknesses of the Pt electrode layer 31, the Pd electrode layer 32 and the Pt electrode layer 33 are about 1 nm, about 5 nm and about 10 nm, respectively, in the aforementioned embodiment, the present invention is not restricted to this but may be formed as in first and second modifications of this embodiment described later, for example.

For example, the p-side ohmic electrode 25 maybe so formed that the thicknesses of the Pt electrode layer 31, the Pd electrode layer 32 and the Pt electrode layer 33 are about 1.5 nm, about 10 nm and about 30 nm, respectively, as the first modification of the embodiment. Also when the Pt electrode layer 31 has a thickness of about 1.5 nm, the Pt electrode layer 31 is formed in the state where Pt is distributed in the form of islands on the surface of the p-type contact layer 24 and a part thereof spreads in the form of a net on the p-type contact layer 24 in plan view, as shown in FIG. 2. The surface of the Pt electrode layer 33 is difficult to be altered in the manufacturing process also when being formed as in this first modification, and hence an alteration layer is inhibited from formation on the surface of the p-side ohmic electrode 25.

The p-side ohmic electrode 25 may be so formed that the thicknesses of the Pt electrode layer 31, the Pd electrode layer 32 and the Pt electrode layer 33 are about 1 nm, about 15 nm and about 30 nm, respectively, as in the second modification of the embodiment. The surface of the Pt electrode layer 33 is difficult to be altered in the manufacturing process also when being formed as in this second modification, and hence an alteration layer is inhibited from formation on the surface of the p-side ohmic electrode 25.

[Confirmatory Experiment]

Confirmatory experiment 1 according to Example and Comparative Example conducted for confirming the effects of the aforementioned embodiment and confirmatory experiments 2 to 4 conducted for investigating optimum values of thicknesses of the respective metal layers (first, second and third metal layers) constituting the electrode layer of the present invention will be hereinafter described.

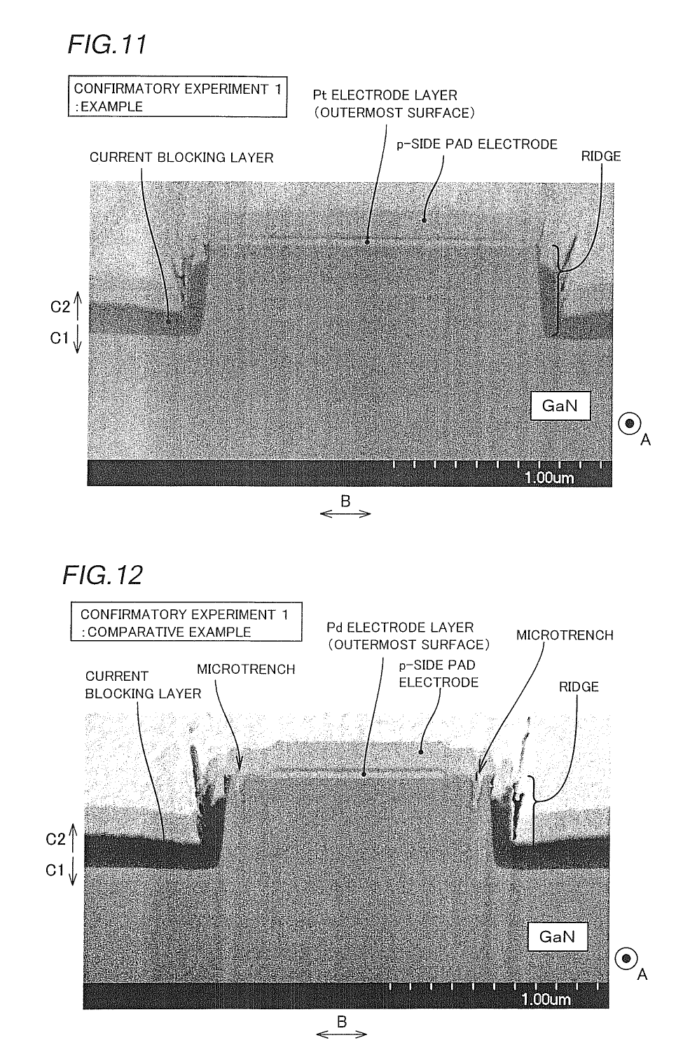

Confirmatory experiment 1 according to Example and Comparative Example conducted for confirming the effects of the aforementioned embodiment will be now described with reference to FIGS. 11 and 12. FIG. 11 is a photomicrograph obtained by observing a sectional device structure in the vicinity of a ridge of a semiconductor laser device formed through the manufacturing process of the nitride-based semiconductor laser device 100 according to the aforementioned embodiment with a SEM, and FIG. 12 is a photomicrograph obtained by observing a sectional device structure in the vicinity of a ridge of a semiconductor laser device formed through a manufacturing process of a conventional semiconductor laser device with the SEM.

In confirmatory experiment 1, a nitride-based semiconductor laser device according to Example corresponding to the aforementioned embodiment was prepared through a manufacturing process similar to that of the aforementioned embodiment. Additionally, a nitride-based semiconductor laser device according to Comparative Example corresponding to the aforementioned Example was prepared through a manufacturing process of the conventional semiconductor laser device. In other words, in this Comparative Example, an ohmic electrode layer having an outermost surface of a Pd-based electrode layer was formed by stacking a Pt electrode layer and a Pd electrode layer in this order on a p-side semiconductor layer made of a nitride-based semiconductor, and a ridge was thereafter formed through the manufacturing process similar to that of the aforementioned embodiment.

From the result of observation of the prepared laser device, it has been confirmed in Comparative Example shown in FIG. 12 that while the ridge (projecting portion) was formed on a nitride-based semiconductor layer, the ridge had an abnormal etching shape from the vicinity of ends of an upper surface of the ridge to the nitride-based semiconductor layer located on a lower portion. The reason for the abnormal shape of the ridge is conceivably because when patterning the ohmic electrode in a striped matter by dry etching in the manufacturing process, fine grooves or holes (microtrenches) caused by etching the etched surfaces (both side surface) of the Pd electrode layer were partially formed due to the Pd electrode layer arranged on the outermost surface. While protective films by fluorocarbon-based substances generated by CHF₃ gas or substances (mainly Pt or Pd) of scattering electrode materials were formed on the etched surfaces of the Pd electrode layer, Pd was a metal material easily causing the fine grooves or holes (microtrenches) by etching, and hence the aforementioned protective films did not effectively protect the etched surfaces. Thereafter, not only the semiconductor layer but also the fine grooves (microtrenches) of the aforementioned Pd electrode layer secondarily formed were simultaneously etched when forming the ridge by etching the semiconductor layer through the striped ohmic electrode serving as a mask. As a result, grooves or holes passing through the ohmic electrode were formed from the surface of the ohmic electrode toward the semiconductor layer (p-type cladding layer), and hence the ridge was conceivably formed to partially have the abnormal shape.

In Example shown in FIG. 11, on the other hand, it has been confirmed that the ridge (projecting portion) formed on the nitride-based semiconductor layer had no abnormal shape confirmed in the aforementioned Comparative Example. In other words, when the ohmic electrode layer was dry etched in a state where the Pt electrode layer having a thickness (thickness: 25 nm) five times the thickness of the Pd electrode layer (thickness: 5 nm) which was an intermediate layer was formed on the outermost surface of the ohmic electrode layer, the thick metal materials made of Pt which was difficult to cause fine grooves (microtrenches) on the outermost surface as compared with the Pd electrode layer were deposited, and hence the ohmic electrode was conceivably able to be formed without causing microtrenches on the Pt electrode layer or the like in etching. Consequently, the semiconductor layer was etched through the ohmic electrode with no microtrench serving as a mask, and hence no abnormal shape was conceivably formed also on the ridge formed by etching.

Form the aforementioned results of confirmatory experiment 1, it has been confirmed that the ohmic electrode and the ridge having proper shapes as a laser device was able to be formed when the semiconductor laser device was formed through the manufacturing process of the nitride-based semiconductor laser device according to the present invention.

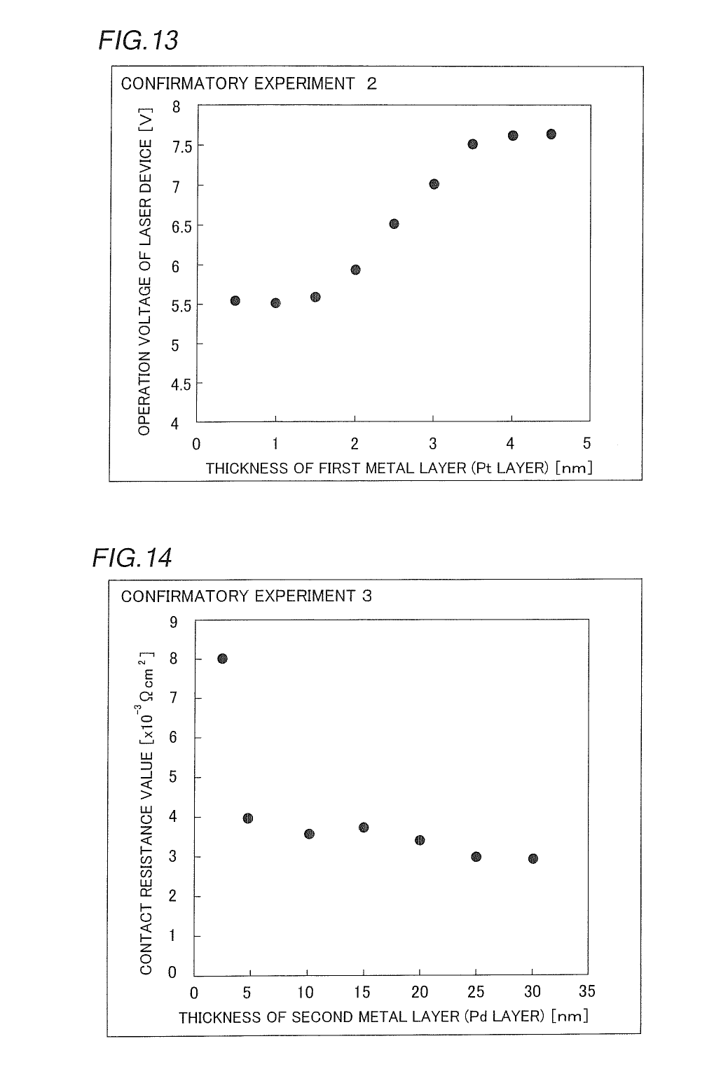

Confirmatory experiment 2 conducted for investigating the optimum value of the thickness of the first metal layer (Pt layer) of the present invention will be now described with reference to FIGS. 1 and 13.

In confirmatory experiment 2, nitride-based semiconductor laser devices having device structures similar to that of the nitride-based semiconductor laser device 100 corresponding to the embodiment shown in FIG. 1 were prepared. At this time, the nitride-based semiconductor laser devices having the p-side electrode layers (p-side ohmic electrode 25 in FIG. 1) including the first metal layers (Pt layers), thicknesses of which were varied from 0.5 nm to 4.5 every 0.5 nm, in contact with the p-type contact layers of the nitride-based semiconductor laser devices were prepared (the number of samples: n=9). Then, operation voltages of the respective nitride-based semiconductor laser devices were investigated.

As a result of the experiment, it has been confirmed that the operation voltage of the nitride-based semiconductor laser device was the lowest (5.5 V), when the thickness of the first metal layer (Pt layer 31) in contact with the p-type contact layer is about 1 nm, as shown in FIG. 13. Also when the thickness of the first metal layer was at most 2 nm, the operation voltage of at most 6 V which was relatively low was obtained. On the other hand, it has been confirmed that the operation voltage tended to increase when thickness of the first metal layer exceeded about 2 nm. When the thickness of the first metal layer was 0.5 nm, the thickness of the film in forming the metal film was not be able to be properly controlled and the first metal layer having a uniform thickness was not be able to be formed. Therefore, it has been proved in this confirmatory experiment 2 that the thickness of the first metal layer (Pt layer) was preferably at least 1 nm and not more than 2 nm.

Confirmatory experiment 3 conducted for investigating the optimum value of the thickness of the second metal layer (Pd layer) of the present invention will be now described with reference to FIGS. 1, 14 to 16.

In confirmatory experiment 3, nitride-based semiconductor laser devices having device structures similar to those of the aforementioned confirmatory experiment 2 were prepared. At this time, the nitride-based semiconductor laser devices having the p-side electrode layers (p-side ohmic electrode 25 in FIG. 1) including the second metal layers (Pd layers), thicknesses of which were varied from 2 nm to 30 nm, formed on the first metal layers (Pt layers) were prepared (the number of samples: n=7). Then, contact resistance values of the second metal layers of the respective nitride-based semiconductor laser devices were investigated. The thicknesses of each first metal layer (Pt layer) and each third metal layer (Pt layer) were constant values of 1 nm and 10 nm, respectively. In the manufacturing processes of preparing each nitride-based semiconductor laser device, the quantity of adherence of the electrode materials scattering from the p-side electrode layer (lateral width of the films (protective films) made of fluorocarbon-based substances adhering to the side surfaces in the vicinity of the p-side electrode layer or substances of the scattering electrode materials mainly composed of Pt and Pd) in forming the ridge by anisotropic dry etching through the p-side electrode layer serving as a mask was investigated. It has been confirmed that the electrode materials (protective films) scattering from the p-side electrode layer following etching adhered to the side surfaces in the vicinity of the p-side electrode layer (ridge) with progression of etching in a stage shown in FIG. 16. In FIG. 16, the lateral width of the portion where Pd adhered to the side surfaces in the vicinity of the p-side electrode layer is represented by W1 and W2. In confirmatory experiment 3, anisotropic dry etching was so performed in a state of pattering the mask on the p-side electrode layer as to have a width of 1.3 μm.

From the result of the measurement of the contact resistance value with respect to the thickness of each second metal layer, the contact resistance value was 8×10⁻³ Ωcm⁻³ when the thickness of the second metal layer was about 2 nm, while the contact resistance value was kept in the range of at least 3×10⁻³ Ωcm⁻³ and not more than 4×10⁻³ Ωcm⁻³ when the thickness of the second metal layer was in the range of at least 5 nm and not more than 30 nm, as shown in FIG. 14.

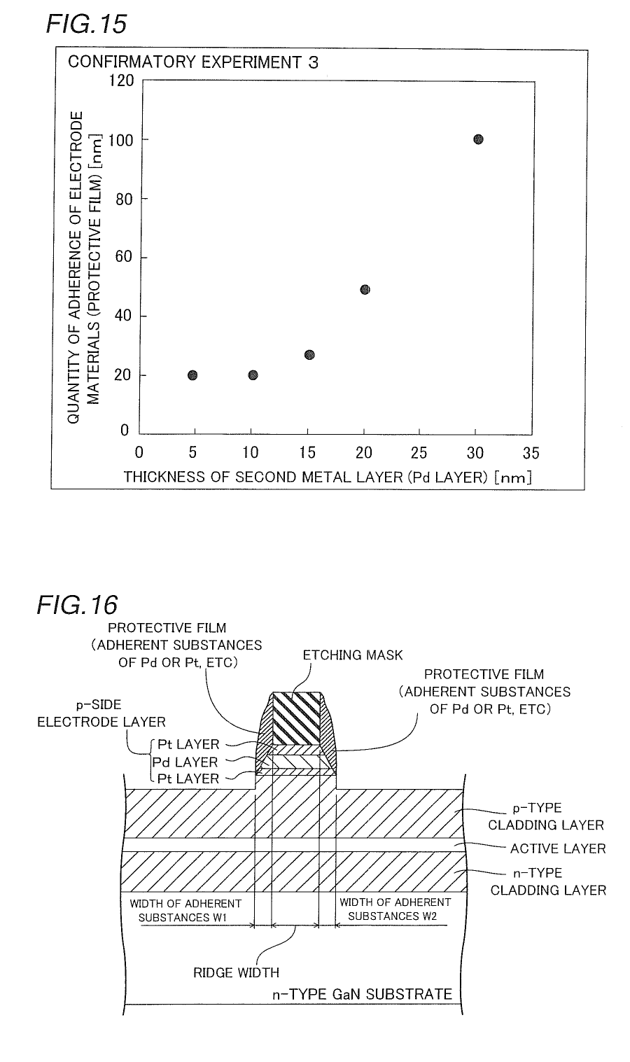

From the result of the measurement of the quantity of adherence of Pd with respect to the thickness of each second metal layer in dry etching (measurement is 5 points only), the lateral width (W1+W2) of the adherent substances was at most 30 nm when the thickness of the second metal layer was in the range of at least 5 nm and not more than 15 nm, as shown in FIG. 15. On the other hand, the lateral width (W1+W2) of the adherent substances was remarkably increased to the range from 50 nm to 100 nm when the thickness of the second metal layer was in the range of at least 20 nm and not more than 30 nm. When the quantity of adherence of the electrode materials was 100 nm (W1+W2 shown in FIG. 16), it was considerably large with respect to a width of the ridge (1.3 μm), and hence it has been conceivably required that the thickness of the second metal layer was kept below 30 nm. Particularly, the thickness of the second metal layer must be kept at most 20 nm in order to keep the quantity of adherence (W1+W2) of the electrode materials at most 50 nm.

Confirmatory experiment 4 conducted for investigating the optimum value of the thickness of the third metal layer (Pt layer) of the present invention will be now described with reference to FIGS. 1 and 15 and 17.

In confirmatory experiment 4, nitride-based semiconductor laser devices having device structures similar to those of the aforementioned confirmatory experiments 2 and 3 were prepared. At this time, the third metal layers, thicknesses of which were varied from 10 nm to 40 nm every 10 nm, constituting the outermost surfaces of the p-side electrode layers (p-side ohmic electrodes 25 in FIG. 1) were stacked, and the respective ridges were thereafter formed by anisotropic dry etching through the electrode layers serving as masks (the number of samples: n=4). Similarly to the aforementioned confirmatory experiment 3, the quantity of adherence of the electrode materials and the like scattering from each p-side electrode layer (lateral width of the portions adhering to side surfaces in the vicinity of the p-side electrode layer) was investigated. The thicknesses of each first metal layer and each second metal layer were constant values of 1 nm and 5 nm, respectively.

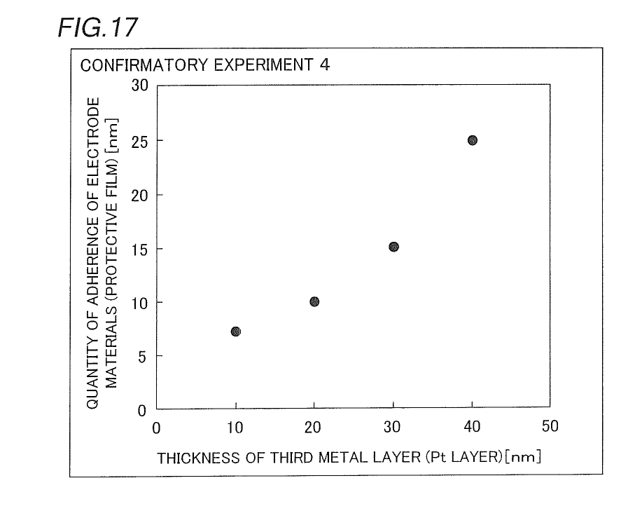

From the results of the experiment, it has been confirmed that the lateral width (W1+W2) of the adhered electrode materials tended to increase with increase of the thickness of the third metal layer, as shown in FIG. 17. From the results of the aforementioned confirmatory experiment 3 shown in FIG. 15, the thickness of the second metal layer was conceivably preferably at least 5 nm and not more than 20 nm in order to keep the quantity of adherence (lateral width (W1+W2) of the adherent substances) of the electrode materials in forming the ridge by dry etching at most 50 nm as a target value. In this case, the quantity of adherence (see FIG. 17) of the electrode materials must be at most 15 nm. Therefore, it has been conceivably required from FIG. 17 that the thickness of the third metal layer was in the range of at least 10 nm and not more than 30 nm.

From the results of the aforementioned confirmatory experiments 2 to 4, the thickness of the second metal layer (Pd layer) is preferably determined according to a formation condition (thickness) of the third metal layer (Pt layer) as described below, in order to keep the quantity of adherence (width W1+W2 in FIG. 16) of the electrode materials in dry etching at most 50 nm. First, it is conceivably required that the thickness of the second metal layer (Pd layer) is at least 5 nm and not more than 20 nm when the thickness of the third metal layer (Pt layer) is about 10 nm. Second, it is conceivably required that the thickness of the second metal layer (Pd layer) is at least 5 nm and not more than 15 nm when the thickness of the third metal layer (Pt layer) is about 20 nm. Third, it is conceivably required that the thickness of the second metal layer (Pd layer) is at least 5 nm and not more than 16 nm when the thickness of the third metal layer (Pt layer) is about 30 nm. In any of the aforementioned three cases, the thickness of the first metal layer (Pt layer) is preferably at least 1 nm and not more than 2 nm.

Although the present invention has been described and illustrated in detail, it is clearly understood that the same is by way of illustration and example only and is not to be taken by way of limitation, the spirit and scope of the present invention being limited only by the terms of the appended claims.

For example, while the p-side ohmic electrode 25 is formed by combining the thicknesses of the Pt electrode layer 31, the Pd electrode layer 32 and the Pt electrode layer 33 in each of the aforementioned embodiment and the modification thereof, the present invention is not restricted to this but the p-side ohmic electrode 25 may be formed by stacking the respective electrode layers 31, 32 and 33 to have the thicknesses other than those shown in each of the aforementioned embodiment and the modification thereof. The thickness of the Pt electrode layer 33 is at least 10 times and not more than 30 times the thickness of the Pt electrode layer 31.

While the thickness of the Pd electrode layer 32 is smaller than that of the Pt electrode layer 33 in each of the aforementioned embodiment and the modification thereof, the present invention is not restricted to this but the thickness of the Pd electrode layer 32 may be substantially the same as that of the Pt electrode layer 33 or may be slightly larger than that of the Pt electrode layer 33.

While the Pt electrode layer 31 is provided in the form of islands on the surface of the p-type contact layer 24 in each of the aforementioned embodiment and the modification thereof, the present invention is not restricted to this but the Pt electrode layer 31 may be formed in the form of a layer having a substantially constant thickness.

While the Pd electrode layer 32 is stacked to be in contact with the Pt electrode layer 31 in each of the aforementioned embodiment and the modification thereof, the present invention is not restricted to this but an electrode layer made of Ti maybe interposed between the Pt electrode layer 31 (first metal layer) and the Pd electrode layer 32 (second metal layer). Particularly, the thickness of the electrode layer made of Ti is preferably at least about 0.5 nm and not more than about 2 nm in this case.

While the mask 40 and the p-side ohmic electrode 25 are patterned through the resist pattern 41 serving as the mask, and the resist pattern 41 is then removed, and the ridge 30 is thereafter formed by employing the patterned mask 40 and p-side ohmic electrode 25 as the masks in the manufacturing process of each of the aforementioned embodiment and the modification thereof, the present invention is not restricted to this but the ridge 30 may be formed by employing the resist pattern 41, the mask 40 and the p-side ohmic electrode 25 as masks without removing the resist pattern 41 after pattering the mask 40 and the p-side ohmic electrode 25. In the case of this modification, both of the resist pattern 41 and the mask 40 are the “first mask layer” in the present invention. Alternatively, the resist pattern 41 may be formed directly on the p-side ohmic electrode 25 without forming the mask 40, the p-side ohmic electrode 25 may be patterned through the resist pattern 41 serving as a mask, and the ridge 30 may be formed by employing the resist pattern 41 and the p-side ohmic electrode 25 as masks without removing the resist pattern 41. In the case of this modification, only the resist pattern 41 is the “first mask layer” in the present invention.

While the mask 40 and the p-side ohmic electrode 25 are patterned through the prescribed shaped resist pattern 41 serving as the mask in the manufacturing process of each of the aforementioned embodiment and the modification thereof, the present invention is not restricted to this but the resist pattern having the opening with substantially the same width as that of the ridge 30 may be formed on the nitride-based semiconductor layer, the electrode layer and the mask layer may be stacked in this order on the portion, exposed form the opening, of the nitride-based semiconductor layer, and may be formed by lift-off for removing the resist pattern. Thus, the electrode layer and the mask layer having substantially the same widths as that the ridge 30 formed on the nitride-based semiconductor layer can be thereafter formed on the nitride-based semiconductor layer.

While the nitride-based semiconductor laser device 100 is formed by stacking the nitride-based semiconductor on the n-type GaN substrate 11 (growth substrate) in each of the aforementioned embodiment and the modification thereof, the present invention is not restricted to this but a wafer of the nitride-based semiconductor laser device may be formed by stacking the nitride-based semiconductor on the n-type GaN substrate 11 and thereafter the p-side pad electrode 27 side of the wafer, employed as a bonded surface, may be bonded to a support substrate made of Ge, and the nitride-based semiconductor laser device may be formed by re-bonding for removing the n-type GaN substrate 11.

While the nitride-based semiconductor laser device 100 having the single ridge 30 is formed in each of the aforementioned embodiment and the modification thereof, the present invention is not restricted to this but a nitride-based semiconductor laser device having two or more light-emitting portions may be formed by forming two or more ridges on the nitride-based semiconductor layer.

While the nitride-based semiconductor laser device 100 having the single ridge 30 is formed on the n-type GaN substrate in each of the aforementioned embodiment and the modification thereof, the present invention is not restricted to this but nitride-based semiconductor layers may be formed on the n-type GaN substrate 11 to be adjacent to each other at a prescribed interval, and a monolithic multiple wavelength semiconductor laser device (two-wavelength semiconductor laser device consisting of blue and green laser divides, for example) provided with ridges on the respective nitride-based semiconductor layers may be formed.

What is claimed is:

1. A nitride-based semiconductor laser device comprising:
a nitride-based semiconductor layer formed on an active layer made of a nitride-based semiconductor; and
an electrode layer including a first metal layer, made of Pt, formed on a far side of a surface of said nitride-based semiconductor layer from said active layer, a second metal layer, made of Pd, formed on a surface of said first metal layer, and a third metal layer, made of Pt, formed on a surface of said second metal layer, and having a prescribed shape in plan view, wherein
a thickness of said third metal layer is at least 10 times and not more than 30 times a thickness of said first metal layer.

2. The nitride-based semiconductor laser device according to claim 1, wherein
said first metal layer is formed to partially cover said surface of said nitride-based semiconductor layer, and
said second metal layer is formed to cover the surface of said first metal layer and said surface, not covered by said first metal layer, of said nitride-based semiconductor layer.

3. The nitride-based semiconductor laser device according to claim 2, wherein
said first metal layer is formed in a state where Pt is distributed in the form of islands or a state where Pt is in the form of a net.

4. The nitride-based semiconductor laser device according to claim 1, wherein
said first metal layer has the thickness in the range of at least about 1 nm and not more than about 2 nm.

5. The nitride-based semiconductor laser device according to claim 1, wherein
the thickness of said first metal layer is smaller than a thickness of said second metal layer.

6. The nitride-based semiconductor laser device according to claim 1, wherein
said second metal layer has the thickness in the range of at least about 5 nm and not more than about 20 nm.

7. The nitride-based semiconductor laser device according to claim 1, wherein
a thickness of said second metal layer is smaller than the thickness of said third metal layer.

8. The nitride-based semiconductor laser device according to claim 7, wherein
said third metal layer has the thickness in the range of at least about 10 nm and not more than about 30 nm.

9. The nitride-based semiconductor laser device according to claim 1, wherein
said prescribed shape is substantially the same shape as a shape of a current path of said active layer formed below said electrode layer in plan view.

10. The nitride-based semiconductor laser device according to claim 1, wherein
said prescribed shape is substantially the same shape as a shape of an optical waveguide formed below said electrode layer in plan view.

11. The nitride-based semiconductor laser device according to claim 1, further comprising a ridge formed on said far side and formed below said electrode layer to have substantially the same shape as said prescribed shape in plan view, wherein
said first metal layer made of Pt is formed on said ridge.

12. The nitride-based semiconductor laser device according to claim 11, wherein
a width of a near side of said first metal layer to said nitride-based semiconductor layer is larger than that of a far side of said third metal layer from said nitride-based semiconductor layer.

13. The nitride-based semiconductor laser device according to claim 11, wherein
said electrode layer includes a side surface extending along an extensional direction of said ridge, and
said side surface is inclined to increase a width of said electrode layer from said third metal layer toward said first metal layer.

14. The nitride-based semiconductor laser device according to claim 1, wherein
said electrode layer is an ohmic electrode.

15. The nitride-based semiconductor laser device according to claim 14, further comprising a pad electrode formed on a side of said third metal layer opposite to said second metal layer, wherein
said pad electrode is in contact with a surface of said third metal layer.

16. The nitride-based semiconductor laser device according to claim 15, wherein
said pad electrode contains Au.

17. The nitride-based semiconductor laser device according to claim 1, wherein
said nitride-based semiconductor layer includes a p-type semiconductor layer, and
said electrode layer is a p-side electrode.

18. A method of manufacturing a nitride-based semiconductor laser device, comprising steps of
forming a nitride-based semiconductor layer on an active layer made of a nitride-based semiconductor;
stacking a first metal layer made of Pt, a second metal layer made of Pd, a third metal layer, made of Pt, having a thickness of at least 10 times and not more than 30 times a thickness of said first metal layer and a first mask layer in this order on a far side of a surface of said nitride-based semiconductor layer from said active layer, to form said first, second and third metal layers and said first mask layer in a state of having a prescribed shape in plan view; and
forming a ridge having said prescribed shape on said nitride-based semiconductor layer by etching said nitride-based semiconductor layer through said first mask layer and said third, second and first metal layers serving as masks.

19. The method of manufacturing a nitride-based semiconductor laser device according to claim 18, wherein
said step of stacking said first, second and third metal layers and said first mask layer in this order, to form said first, second and third metal layers and said first mask layer in the state of having said prescribed shape in plan view includes a step of forming said first, second and third metal layers in a state of having said prescribed shape in plan view by etching said third, second and first metal layers through said first mask layer serving as a mask.

20. The method of manufacturing a nitride-based semiconductor laser device according to claim 18, further comprising steps of:
forming a current blocking layer made of an insulating film on a surface of said nitride-based semiconductor layer and surfaces of said third, second and first metal layers formed in the state of having said prescribed shape,
forming a second mask layer having an opening to correspond to a portion located above at least said ridge of said current blocking layer,
exposing a surface of said third metal layer by removing said current blocking layer on a portion exposed from said opening through said second mask serving as a mask, and
removing said second mask layer.
